(19) United States
(12) Patent Application Publication
(10) Pub. No.: US 2022/0170173 A1
(43) Pub. Date: Jun. 2, 2022

(54) SUBSTRATE CARRIER AND ELECTROCHEMICAL DEPOSITION SYSTEM

(71) Applicant: BOE Technology Group Co., Ltd., Beijing (CN)

(72) Inventors: Shihao DONG, Beijing (CN); Junwei YAN, Beijing (CN); Guocai ZHANG, Beijing (CN); Chengfei WANG, Beijing (CN); Shaodong SUN, Beijing (CN); Pengcheng DONG, Beijing (CN)

(21) Appl. No.: 17/401,167

(22) Filed: Aug. 12, 2021

(30) Foreign Application Priority Data
Nov. 30, 2020 (CN) 202022838407.5

(51) Int. Cl. C25D 17/06; H01R 13/24; C25D 7/12

(52) U.S. Cl. CPC C25D 17/06; H01L 21/68721; C25D 7/12; H01R 13/2407

(57) ABSTRACT

A substrate carrier includes: a carrier body, wherein the carrier body includes at least one carrying surface, and a first conductive sheet is provided on the carrying surface; a cover plate, wherein the cover plate is a frame structure with a hollow interior, the cover plate is opposite to the carrying surface and is detachably fixed on the carrying surface, the shape of the frame structure matches the shape of a substrate to be coated, the cover plate includes an inner side surface facing the carrying surface, and a second conductive sheet is provided on the inner side surface; an elastic connector is provided between the first conductive sheet and the second conductive sheet, and when the substrate to be coated is fixed on the carrying surface, the second conductive sheet is respectively in electrical communication with the conductive film layer and the first conductive sheet via the elastic connector.

### CROSS-REFERENCE TO RELATED APPLICATIONS

The present application claims priority to Chinese Patent Application No. 202022838407.5 filed in China on Nov. 30, 2020, which is incorporated herein by reference in its entirety.

### TECHNICAL FIELD

The present disclosure relates to the field of electrochemical deposition technology, and more particularly to a substrate carrier and electrochemical deposition system.

### BACKGROUND

Electrochemical deposition process can be used to prepare metal film layer on the substrate. The substrate carrier used in electrochemical deposition system is the focus and difficulty of electrochemical deposition. Due to the limitations imposed by the process environment, the substrate carrier needs to be resistant to acid and alkali corrosion. Also, as carrier of the substrate, the substrate carrier needs to uniformly and smoothly conduct current to the entire substrate surface while reducing the fragmentation rate of the substrate.

### SUMMARY

In a first aspect, embodiments of the present disclosure provide a substrate carrier for carrying a substrate to be coated, the substrate to be coated including a first surface and a second surface arranged opposite to each other, the first surface being provided with a conductive film layer, the substrate carrier including: a carrier body, wherein the carrier body includes at least one carrying surface for carrying and fixing the substrate to be coated, and a first conductive sheet is provided on the carrying surface; and a cover plate, the cover plate including a frame structure with a hollow interior, the cover plate being opposite to the carrying surface and being detachably fixed on the carrying surface, a shape of the frame structure matching a shape of the substrate to be coated, the cover plate being configured to be fixed on the carrying surface and being in contact with the first surface of the substrate to be coated, the cover plate including an inner side surface facing the carrying surface, and a second conductive sheet being provided on the inner side surface. And an elastic connector is provided between the first conductive sheet and the second conductive sheet, and when the substrate to be coated is fixed on the carrying surface, the second conductive sheet is respectively in electrical communication with the conductive film layer and the first conductive sheet via the elastic connector.

According to one possible embodiment of the present disclosure, the elastic connector includes: at least one of an elastic pogo pin, a spring, or a deflectable dome.

According to one possible embodiment of the present disclosure, when the substrate to be coated is fixed on the carrying surface, a part of an orthographic projection of the second conductive sheet onto the carrying surface coincides with an orthographic projection of the first conductive sheet onto the carrying surface, and another part of the orthographic projection of the second conductive sheet onto the carrying surface coincides with an orthographic projection of the conductive film layer onto the carrying surface.

According to one possible embodiment of the present disclosure, a fixing mechanism for limiting and fixing the substrate to be coated on the carrying surface is further provided on the carrier body.

According to one possible embodiment of the present disclosure, the fixing mechanism includes: one or more first vacuum adsorption holes provided on the carrying surface; and a first vacuum line connected to the first vacuum adsorption holes, wherein the first vacuum line is provided inside the carrier body.

According to one possible embodiment of the present disclosure, the first conductive sheet is embedded in the carrier body and exposed at a surface of the carrying surface.

According to one possible embodiment of the present disclosure, the cover plate is detachably connected to the carrier body in an adsorbing manner.

According to one possible embodiment of the present disclosure, the cover plate is provided with one or more first magnetic components on the inner side surface; the carrier body is provided with one or more second magnetic components for generating a magnetic attraction force with the first magnetic components at a peripheral region of the carrying surface.

According to one possible embodiment of the present disclosure, the first conductive sheet includes four sub-conductive sheets, a first sub-conductive sheet of the four sub-conductive sheets is connected to a third conductive sheet, and the third conductive sheet extends to an edge of the carrier body and is used for connecting to an external rectifier.

According to one possible embodiment of the present disclosure, the cover plate includes a cover plate main body, the cover plate main body is in a frame structure, a groove is provided on an inner side surface of the cover plate main body, and the second conductive sheet is provided in the groove.

In a second aspect, embodiments of the present disclosure also provide an electrochemical deposition system including a substrate carrier for carrying a substrate to be coated, the substrate to be coated including a first surface and a second surface arranged opposite to each other, the first surface being provided with a conductive film layer, the substrate carrier including: a carrier body, wherein the carrier body includes at least one carrying surface for carrying and fixing the substrate to be coated, and a first conductive sheet is provided on the carrying surface; and a cover plate, the cover plate including a frame structure with a hollow interior, the cover plate being opposite to the carrying surface and being detachably fixed on the carrying surface, a shape of the frame structure matching a shape of the substrate to be coated, the cover plate being configured to be fixed on the carrying surface and being in contact with the first surface of the substrate to be coated, the cover plate including an inner side surface facing the carrying surface, and a second conductive sheet being provided on the inner side surface. And an elastic connector is provided between the first conductive sheet and the second conductive sheet, and when the substrate to be coated is fixed on the carrying surface, the second conductive sheet is respectively in electrical communication with the conductive film layer and the first conductive sheet via the elastic connector.

According to one possible embodiment of the present disclosure, the elastic connector includes: at least one of an elastic pogo pin, a spring, or a deflectable dome.

According to one possible embodiment of the present disclosure, when the substrate to be coated is fixed on the carrying surface, a part of an orthographic projection of the second conductive sheet onto the carrying surface coincides with an orthographic projection of the first conductive sheet onto the carrying surface, and another part of the orthographic projection of the second conductive sheet onto the carrying surface coincides with an orthographic projection of the conductive film layer onto the carrying surface.

According to one possible embodiment of the present disclosure, a fixing mechanism for limiting and fixing the substrate to be coated on the carrying surface is further provided on the carrier body.

According to one possible embodiment of the present disclosure, the fixing mechanism includes: one or more first vacuum adsorption holes provided on the carrying surface; and a first vacuum line connected to the first vacuum adsorption holes, wherein the first vacuum line is provided inside the carrier body.

According to one possible embodiment of the present disclosure, the first conductive sheet is embedded in the carrier body and exposed at a surface of the carrying surface.

According to one possible embodiment of the present disclosure, the cover plate is detachably connected to the carrier body in an adsorbing manner.

According to one possible embodiment of the present disclosure, the cover plate is provided with one or more first magnetic components on the inner side surface; the carrier body is provided with one or more second magnetic components for generating a magnetic attraction force with the first magnetic components at a peripheral region of the carrying surface.

According to one possible embodiment of the present disclosure, the first conductive sheet includes four sub-conductive sheets, a first sub-conductive sheet of the four sub-conductive sheets is connected to a third conductive sheet, and the third conductive sheet extends to an edge of the carrier body and is used for connecting to an external rectifier.

According to one possible embodiment of the present disclosure, the cover plate includes a cover plate main body, the cover plate main body is in a frame structure, a groove is provided on an inner side surface of the cover plate main body, and the second conductive sheet is provided in the groove.

### BRIEF DESCRIPTION OF THE DRAWINGS

In order to more clearly explain the embodiments of the present disclosure or the technical solutions in the related art, a brief description will be given below with reference to the accompanying drawings to be used in the description of the embodiments, and it is obvious that the drawings in the description below are only some embodiments of the present disclosure, and other drawings can be obtained from these drawings by a person skilled in the art without involving any inventive effort.

FIG. 1 illustrates a top view of a carrier body in a substrate carrier provided in one embodiment of the present disclosure;

FIG. 2 illustrates a schematic sectional view of a substrate carrier provided in one embodiment of the present disclosure when a carrier body cooperates with a cover plate to carry a substrate; and

FIG. 3 illustrates a schematic exploded view of a cover plate main body and a second conductive sheet of a cover plate of a substrate carrier provided in one embodiment of the present disclosure.

### DETAILED DESCRIPTION

To further clarify the objects, technical solutions and advantages of the embodiments of the present disclosure, a more particular description of the technical solutions of the present disclosure will be rendered by reference to the appended drawings. Obviously, the embodiments described in the present disclosure are part of the all embodiments, in which some, but not all embodiments of the disclosure are shown. Based on the embodiments described in the present disclosure, all other embodiments obtained by a person of ordinary skill in the art without inventive effort are within the scope of protection of this disclosure.

Unless defined otherwise, technical or scientific terms used in this disclosure shall have the ordinary meaning as understood by one of ordinary skill in the art to which this disclosure belongs. As used in this disclosure, the terms “first”, “second” and the like do not denote any order, quantity, or importance, but rather are used to distinguish one component from another. Similarly, the use of the terms “one”, “a/an” or “the” do not denote a limitation of quantity, but rather denote the presence of at least one. The word “comprise” or “include” or the like, means that the element or object preceded by the word is inclusive of the element or object listed after the word and its equivalents, and does not exclude other elements or objects. Similar terms such as “connect” or “connected” are not limited to physical or mechanical connections, but may include electrical connections, whether direct or indirect. “Upper”, “lower”, “left”, “right” and the like are used merely to denote relative positional relationships, which may change accordingly when the absolute position of the subject being described changes.

Before describing the substrate carrier and the electrochemical deposition system provided by the embodiments of the present disclosure in detail, it is necessary to describe the related art as follows: in the related art, in an electrochemical deposition process, a piece to be plated is used as a cathode, and then a metal thin film is deposited on the piece to be plated, and a substrate carrier needs to conduct current uniformly and smoothly to the entire glass surface while reducing the fragmentation rate of a panel.

Embodiments of the present disclosure provide a substrate carrier and an electrochemical deposition system capable of achieving uniform current distribution on the surface of a panel during electrochemical deposition, thereby achieving a uniform electrochemical deposition process.

The embodiment of the present disclosure provides a substrate carrier capable of carrying and fixing a substrate to be coated so that the substrate to be coated is electrochemically deposited, wherein the substrate to be coated can be various substrates to be coated including a glass substrate, etc., the substrate to be coated includes a first surface and a second surface arranged opposite to each other, and the first surface is provided with a conductive film layer. Taking a glass substrate as an example, the glass substrate itself is non-conductive, and if the glass substrate is electrochemically deposited, it is required to serve as a cathode (or other electrical property). Therefore, a conductive film layer can be provided on the surface of the glass substrate to serve as a seed layer for the electrochemical deposition process.

Note that the conductive film layer may be a conductive film layer separately provided for the purpose of electrochemical deposition, or may be a conductive film layer existing on the substrate to be coated itself. The conductive film layer may be selected from a metal material, for example, a metal including copper or an alloy material.

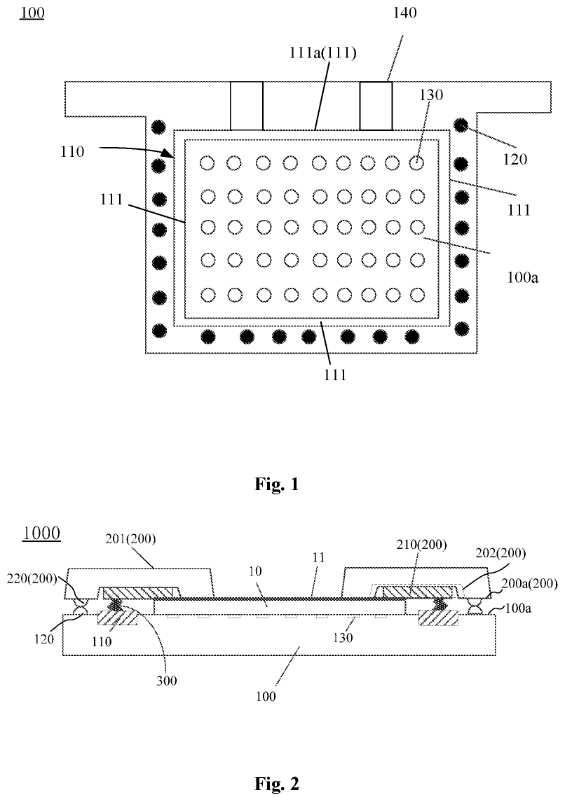

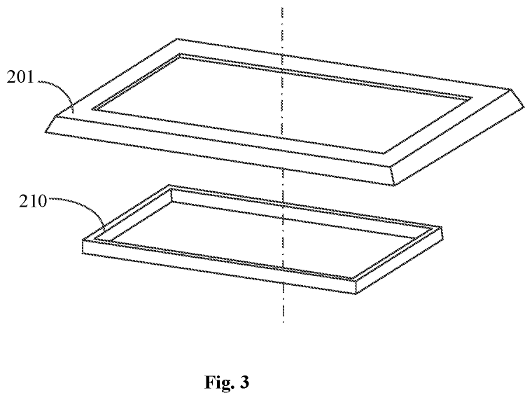

As shown in FIGS. 1 and 2, a substrate carrier 1000 provided in an embodiment of the present disclosure includes:

a carrier body 100, wherein the carrier body 100 includes at least one carrying surface 100a for carrying and fixing a substrate 10 to be coated, and a first conductive sheet 110 for connecting an external rectifier is provided on the carrying surface 100a;

a cover plate 200, wherein the cover plate 200 includes a frame structure with a hollow interior, the cover plate 200 is opposite to the carrying surface and is detachably fixed on the carrying surface 100a, the shape of the frame structure matches the shape of the substrate 10 to be coated, and the cover plate 200 is used for being fixed on the peripheral region of the carrying surface 100a and in contact with the first surface of the substrate 10 to be coated, for example, in direct contact with the edge of the substrate 10 to be coated. The position where the cover plate 200 is in contact with the substrate 10 to be coated needs to be set as long as it does not affect the area where subsequent electrochemical deposition needs to be completed. For example, it can be located at the peripheral area of the substrate to be coated. It is understood that the matching of the shape of the frame structure to the shape of the substrate to be coated means that the outer contour of the shape of the substrate to be coated has a same or similar shape to the outer contour of the shape of the frame structure.

As shown in FIG. 2, the cover plate 200 includes an inner side surface 200a facing the carrying surface 100a, and a second conductive sheet 210 is provided on the inner side surface 200a. An elastic connector 300 is provided between the first conductive sheet 110 and the second conductive sheet 210. When the substrate 10 to be coated is fixed on the carrying surface 100a, the second conductive sheet 210 is respectively in electrical communication with the conductive film layer 11 and the first conductive sheet 110 via the elastic connector 300. It will be appreciated that the orthographic projection of the first conductive sheet 110 onto the carrying surface 100a at least partially coincides with the orthographic projection of the second conductive sheet 210 onto the carrying surface 100a, that the orthographic projection of the second conductive sheet 210 onto the carrying surface 100a at least partially coincides with the orthographic projection of the conductive film layer 11 onto the carrying surface 100a, and that the orthographic projection of the first conductive sheet 110 onto the carrying surface 100a does not coincide with the orthographic projection of the conductive film layer 11 onto the carrying surface 100a.

According to the substrate carrier provided by the embodiments of the present disclosure, by designing and providing a carrier body 100 and a cover plate 200, the carrier body 100 being able to carry and fix a substrate (such as a glass substrate) to be coated 10, the cover plate 200 being detachably fixed on a carrying surface of the carrier body 100, before placing the substrate 10 to be coated, the cover plate 200 being detached from the carrier body 100, and carrying and fixing the substrate 10 to be coated on the carrying surface 100a with the second surface of the substrate 10 to be coated facing the carrying surface 100a and the first surface facing away from the carrying surface 100a. Thereafter, the cover plate 200 is aligned with the carrier body 100 such that the cover plate 200 is aligned with the peripheral region of the carrying surface 100a and fixed to the carrying surface 100a. For example, when the carrier body is quadrilateral, for example, rectangular, the cover plate 200 presses the peripheral edge of the substrate 10 to be coated, and the inner side surface 200a of the cover plate 200 facing the carrying surface 100a is provided with a second conductive sheet 210, and the first conductive sheet 110 communicates with the second conductive sheet 210 via a conductive elastic connector 300, so as to achieve the purpose of electrically conducting the conductive film layer 11 and the first conductive sheet 110. Therefore, when the first conductive sheet 110 on the carrier body 100 is connected to an external power source such as a rectifier, the purpose of enabling the substrate 10 to be coated to conduct an electrical signal can be achieved. For example, the conductive film layer 11 on the substrate 10 to be coated serves as a cathode of an electrochemical deposition system, and forms an electric field with an anode of an electroplating apparatus under power, thereby achieving the purpose of electrochemical deposition on the substrate 10 to be coated. Alternatively, a person skilled in the art would have been able to understand that the conductive film layer 11 on the substrate 10 to be coated acts as an anode of the electrochemical deposition system, and forms an electric field with the cathode in the electroplating apparatus under the condition of power supply, thereby achieving the purpose of electrochemical deposition on the substrate 10 to be coated.

Since the first conductive sheet 110 is arranged around the periphery of the carrying surface 100a and the second conductive sheet 210 is arranged around the periphery of the cover plate 200, the current can be uniformly and smoothly conducted to the entire surface of the substrate 10 to be coated so as to achieve the purpose of uniform electrochemical deposition.

It should be noted that in the above-mentioned disclosed embodiment, the conduction is realized between the conductive film layer 11 on the substrate 10 to be coated and the first conductive sheet 110 on the carrier body 100 via the second conductive sheet 210 provided on the cover plate 200. In this way, while serving the function of conducting the conductive film layer 11 and the first conductive sheet 110, the cover plate 200 can also serve the purpose of fixing the substrate 10 to be coated, and the cover plate 200 can also cover the conducting part of the conductive film layer 11 and the first conductive sheet 110, serving the function of protecting the conducting part; and the structure of each component is simple and the operation is convenient.

In the above-mentioned embodiment, when the peripheral edge of the substrate 10 to be coated is pressed by the cover plate 200, one part of the second conductive sheet 210 on the inner side surface 200a of the cover plate 200 is adhered to and in communication with the conductive film layer 11 on the substrate 10 to be coated, and the other part is in contact and communication with the first conductive sheet 110 on the carrying surface 100a via the elastic connector 300. In this way, the first conductive sheet 110 and the second conductive sheet 210 are both conductive sheet structures, and when manufacturing, the structure is simple, the process is simple, and the operation is convenient as long as the cover plate 200 is fixed on the carrier body 100 during the operation.

Note that the elastic connector 300 can ensure good contact between the first conductive sheet 110 and the second conductive sheet 210.

In some exemplary embodiments, as shown in FIGS. 1 and 2, when the substrate 10 to be coated is fixed on the carrying surface 100a, a part of the orthographic projection of the second conductive sheet 210 onto the carrying surface 100a coincides with the orthographic projection of the first conductive sheet 110 onto the carrying surface 100a, and another part of the orthographic projection of the second conductive sheet 210 onto the carrying surface 100a coincides with the orthographic projection of the conductive film layer 11 onto the carrying surface 100a. Thus, when the cover plate 200 presses the substrate 10 to be coated on the carrier body 100, the first conductive sheet 110, the second conductive sheet 210 and the conductive film layer 11 are in communication.

In some embodiments, as shown in FIGS. 1 and 2, the first conductive sheet 110 is a continuous annular conductive sheet disposed around and at the edge of the carrying surface 100a. Similarly, the second conductive sheet 210 may be a continuous annular conductive sheet disposed around the edge of the cover plate 200. In this way, the current can be further improved to uniformly conduct to the conductive film layer 11 of the substrate 10 to be coated.

The substrate carrier provided by the embodiments of the present disclosure can be applied to various substrates to be coated 10, and particularly can be applied to glass substrates to improve the feasibility and capacity of mass production of the glass substrates.

It should be noted that the elastic connector 300 may be made of a conductive material as a whole, or the elastic connector 300 may be made of an insulating material as a body, and only a surface thereof is plated with a conductive material, thereby achieving electrical connection between the first conductive sheet 110 and the second conductive sheet 210.

In some exemplary embodiments, as shown in FIGS. 1 and 2, the elastic connector 300 includes: at least one of an elastic pogo pin, a spring, or a deflectable dome. For example, the elastic connection may be a copper pin, a copper spring or a bendable copper sheet. In addition, in addition to metallic copper, those skilled in the art will appreciate that the elastic connector 300 may be made of other suitable conductive materials, without limitation.

It should be noted that in some embodiments, the elastic connector 300 may be integrally formed with the first conductive sheet 110. In other embodiments, the elastic connector 300 may be integrally formed by connecting the second conductive sheet 210. In other embodiments, the elastic connector 300 may be integrally formed by simultaneously connecting the first conductive sheet 110 and the second conductive sheet 210.

In some exemplary embodiments, carrier body 100 includes a carrying surface 100a. It will of course be appreciated that in practice the carrier body 100 may have two carrying surfaces 100a, for example carrying surfaces 100a on opposite sides, for the purpose of electrochemical deposition for two substrates simultaneously.

In addition, it should be noted that the carrier body 100 and the cover plate 200 of the substrate carrier in the embodiments of the present disclosure are made of a plastic material which is resistant to acid and alkali corrosion.

In addition, in some exemplary embodiments, the carrier body 100 is further provided with a fixing mechanism for limiting and fixing the substrate 10 to be coated on the carrying surface 100a.

For example, the fixing mechanism includes: a plurality of first vacuum adsorption holes 130 provided on the carrying surface 100a; and a first vacuum line (not shown) connected to the first vacuum adsorption hole 130, the first vacuum line being provided inside the carrier body 100.

In the above-described embodiment, the substrate 10 to be coated is carried and fixed on the carrying surface 100a of the carrier body 100 in such a vacuum adsorption manner by arranging a plurality of first vacuum adsorption holes 130 on the carrying surface 100a. The plurality of first vacuum adsorption holes 130 shown in FIGS. 1 and 2 can be arranged in an array so as to improve the uniformity of the adsorption force of each region in the carrying surface 100a. Of course, the plurality of first vacuum adsorption holes 130 may be arranged in other manners.

In some exemplary embodiments, as shown in FIGS. 1 and 2, the first conductive sheet 110 is embedded within the carrier body 100 and exposed at the surface of the carrying surface 100a.

It will be understood, of course, that in practice, no limitation is placed on the specific arrangement of the first conductive sheet 110 on the carrier body 100.

In addition, as shown in FIGS. 2 and 3, the cover plate 200 includes a cover plate main body 201, the cover plate main body 201 has a frame structure, a groove 202 is provided on an inner side surface 200a of the cover plate main body 201, and a second conductive sheet 210 is provided in the groove 202. In some cases, both the cover plate main body 201 and the second conductive sheet 210 have a frame structure, the central axes of which may substantially coincide. It will be understood, of course, that specific arrangement of the second conductive sheet 110 on the cover plate 200 is not limited in practical applications. For example, instead of providing grooves on the inner side surface 200a of the cover body 201, the second conductive sheet 210 may be connected in some manner directly to the inner side surface 200a of the cover body 201, such as with glue, tape, or other adhesive substance.

Furthermore, in some exemplary embodiments of the present disclosure, the cover plate 200 is detachably connected to the carrier body 100 in an adsorbing manner, and a specific detachable manner may include: magnetic adsorption manner, vacuum adsorption manner, etc.

In some specific exemplary embodiments, as shown in FIGS. 1 and 2, the cover plate 200 is provided with one or more first magnetic components 220 on the inner side surface 200a. The carrier body 100 is provided with one or more second magnetic components 120 for generating a magnetic attraction force with the first magnetic components 220 at a peripheral region of the carrying surface 100a. In this way, the close attachment and release between the cover plate 200 and the carrier body 100 are ensured by the magnetic attraction, and the fragmentation rate of the panel is effectively reduced.

It is noted that in some exemplary embodiments, the first magnetic component 220 may include an electromagnetic component and the second magnetic component 120 may include a permanent magnet. Alternatively, the second magnetic component 120 may include an electromagnetic component and the first magnetic component 220 may include a permanent magnet.

In addition, in order to ensure the uniformity of the electrochemical deposition, in some exemplary embodiments, as shown in FIGS. 1 and 2, the first conductive sheet 110 includes four sub-conductive sheets 111 surrounding the edge of the carrying surface 100a, and a third conductive sheet 140 is connected to the first sub-conductive sheet 111a of the four sub-conductive sheets 111, the third conductive sheet 140 extending from the first conductive sheet 110 to the edge of the carrier body 100, and the third conductive sheet 140 is used for connection with an external rectifier.

In addition, it should be noted that the substrate carrier in the embodiments of the present disclosure can be applied to carry and fix the substrate 10 to be coated in electrochemical deposition. However, the substrate carrier may be used for carrying and fixing a substrate in other applications, and the applications are not limited thereto.

In addition, the substrate carrier can be applied to different sizes of substrates to be coated 10 for electrochemical deposition, and is applicable to the field of electrochemical deposition for glass substrates and the like, and also applicable to the field of electrochemical deposition for semiconductor silicon wafers and the like.

In addition, the substrate carrier provided by the embodiments of the present disclosure can be applied to the related field of electrochemical deposition for metals such as Ni (nickel), Ag (argentum), etc.

In addition, embodiments of the present disclosure provide an electrochemical deposition system including the substrate carrier provided by embodiments of the present disclosure.

It will be apparent that the electrochemical deposition system provided by the embodiments of the present disclosure also has the advantages brought about by the substrate carrier provided by the embodiments of the present disclosure and will not be described in detail herein.

There are several points needs to be explained as follows.

(1) The drawings of the embodiments of the present disclosure relate only to the structures related to the embodiments of the present disclosure, and other structures can be generally designed.

(2) For purposes of clarity, the thickness of layers or areas is exaggerated or reduced in the drawings used to describe the embodiments of the present disclosure, i.e. the drawings are not necessarily to drawn as the actual proportions; it can be understood that when an element such as a layer, film, area or substrate is referred to as being “upper” or “lower” located on the other element, it can be “directly upper” or “lower” located on the other element or intervening elements may be present.

(3) Without conflict, the embodiments of the present disclosure and features of the embodiments may be combined to yield new embodiments.

The above descriptions are only the specific implementation of this disclosure, and the protection scope of this disclosure is not limited thereto, and the protection scope of this disclosure should be subject to the protection scope of the claims.

What is claimed is:

1. A substrate carrier for carrying a substrate to be coated, the substrate to be coated comprising a first surface and a second surface arranged opposite to each other, the first surface being provided with a conductive film layer, the substrate carrier comprising:
a carrier body, wherein the carrier body comprises at least one carrying surface for carrying and fixing the substrate to be coated, and a first conductive sheet is provided on the carrying surface; and
a cover plate, the cover plate comprising a frame structure with a hollow interior, the cover plate being opposite to the carrying surface and being detachably fixed on the carrying surface, a shape of the frame structure matching a shape of the substrate to be coated, the cover plate being configured to be fixed on the carrying surface and being in contact with the first surface of the substrate to be coated, the cover plate comprising an inner side surface facing the carrying surface, and a second conductive sheet being provided on the inner side surface,
wherein an elastic connector is provided between the first conductive sheet and the second conductive sheet, and when the substrate to be coated is fixed on the carrying surface, the second conductive sheet is respectively in electrical communication with the conductive film layer and the first conductive sheet via the elastic connector.

2. The substrate carrier of claim 1, wherein
the elastic connector comprises: at least one of an elastic pogo pin, a spring, or a deflectable dome.

3. The substrate carrier of claim 1, wherein
when the substrate to be coated is fixed on the carrying surface, a part of an orthographic projection of the second conductive sheet onto the carrying surface coincides with an orthographic projection of the first conductive sheet onto the carrying surface, and another part of the orthographic projection of the second conductive sheet onto the carrying surface coincides with an orthographic projection of the conductive film layer onto the carrying surface.

4. The substrate carrier of claim 1, wherein
a fixing mechanism for limiting and fixing the substrate to be coated on the carrying surface is further provided on the carrier body.

5. The substrate carrier of claim 4, wherein
the fixing mechanism comprises:
one or more first vacuum adsorption holes provided on the carrying surface; and
a first vacuum line connected to the first vacuum adsorption holes, wherein the first vacuum line is provided inside the carrier body.

6. The substrate carrier of claim 1, wherein
the first conductive sheet is embedded in the carrier body and exposed at a surface of the carrying surface.

7. The substrate carrier of claim 1, wherein
the cover plate is detachably connected to the carrier body in an adsorbing manner.

8. The substrate carrier of claim 1, wherein
the cover plate is provided with one or more first magnetic components on the inner side surface;
the carrier body is provided with one or more second magnetic components for generating a magnetic attraction force with the first magnetic components at a peripheral region of the carrying surface.

9. The substrate carrier of claim 1, wherein
the first conductive sheet comprises four sub-conductive sheets, a first sub-conductive sheet of the four sub-conductive sheets is connected to a third conductive sheet, and the third conductive sheet extends to an edge of the carrier body and is used for connecting to an external rectifier.

10. The substrate carrier of claim 1, wherein
the cover plate comprises a cover plate main body, the cover plate main body is in a frame structure, a groove is provided on an inner side surface of the cover plate main body, and the second conductive sheet is provided in the groove.

11. An electrochemical deposition system comprising a substrate carrier for carrying a substrate to be coated, the substrate to be coated comprising a first surface and a second surface arranged opposite to each other, the first surface being provided with a conductive film layer, the substrate carrier comprising:
a carrier body, wherein the carrier body comprises at least one carrying surface for carrying and fixing the substrate to be coated, and a first conductive sheet is provided on the carrying surface; and
a cover plate, the cover plate comprising a frame structure with a hollow interior, the cover plate being opposite to the carrying surface and being detachably fixed on the carrying surface, a shape of the frame structure matching a shape of the substrate to be coated, the cover plate being configured to be fixed on the carrying surface and being in contact with the first surface of the substrate to be coated, the cover plate comprising an inner side surface facing the carrying surface, and a second conductive sheet being provided on the inner side surface,
wherein an elastic connector is provided between the first conductive sheet and the second conductive sheet, and when the substrate to be coated is fixed on the carrying surface, the second conductive sheet is respectively in electrical communication with the conductive film layer and the first conductive sheet via the elastic connector.

12. The electrochemical deposition system of claim 11, wherein
the elastic connector comprises: at least one of an elastic pogo pin, a spring, or a deflectable dome.

13. The electrochemical deposition system of claim 11, wherein
when the substrate to be coated is fixed on the carrying surface, a part of an orthographic projection of the second conductive sheet onto the carrying surface coincides with an orthographic projection of the first conductive sheet onto the carrying surface, and another part of the orthographic projection of the second conductive sheet onto the carrying surface coincides with an orthographic projection of the conductive film layer onto the carrying surface.

14. The electrochemical deposition system of claim 11, wherein
a fixing mechanism for limiting and fixing the substrate to be coated on the carrying surface is further provided on the carrier body.

15. The electrochemical deposition system of claim 14, wherein
the fixing mechanism comprises:
one or more first vacuum adsorption holes provided on the carrying surface; and
a first vacuum line connected to the first vacuum adsorption holes, wherein the first vacuum line is provided inside the carrier body.

16. The electrochemical deposition system of claim 11, wherein
the first conductive sheet is embedded in the carrier body and exposed at a surface of the carrying surface.

17. The electrochemical deposition system of claim 11, wherein
the cover plate is detachably connected to the carrier body in an adsorbing manner.

18. The electrochemical deposition system of claim 11, wherein
the cover plate is provided with one or more first magnetic components on the inner side surface;
the carrier body is provided with one or more second magnetic components for generating a magnetic attraction force with the first magnetic components at a peripheral region of the carrying surface.

19. The electrochemical deposition system of claim 11, wherein
the first conductive sheet comprises four sub-conductive sheets, a first sub-conductive sheet of the four sub-conductive sheets is connected to a third conductive sheet, and the third conductive sheet extends to an edge of the carrier body and is used for connecting to an external rectifier.

20. The electrochemical deposition system of claim 11, wherein
the cover plate comprises a cover plate main body, the cover plate main body is in a frame structure, a groove is provided on an inner side surface of the cover plate main body, and the second conductive sheet is provided in the groove.
